(19) United States
(12) Patent Application Publication
(10) Pub. No.: US 2014/0205160 A1
(43) Pub. Date: Jul. 24, 2014

(54) IMAGE SENSING APPARATUS FOR FINGERPRINT IDENTIFICATION AND RELATED DECODER CIRCUIT

(71) Applicant: EMINENT ELECTRONIC TECHNOLOGY CORP. LTD., Hsinchu (TW)

(72) Inventors: TOM CHANG, Taipei City (TW); Kao-Pin Wu, New Taipei City (TW)

(73) Assignee: EMINENT ELECTRONIC TECHNOLOGY CORP. LTD., Hsinchu (TW)

(21) Appl. No.: 14/159,455

(22) Filed: Jan. 21, 2014

Related U.S. Application Data
(60) Provisional application No. 61/754,654, filed on Jan. 21, 2013.

(30) Foreign Application Priority Data
Oct. 16, 2013 (TW) 102137393

(51) Int. Cl. G06K 9/00; H01L 27/146

(52) U.S. Cl. CPC G06K 9/00013; H01L 27/14625
USPC 382/124; 250/208.1

(57) ABSTRACT

An image sensing apparatus includes a substrate, a light guide plate, a plurality of photosensors and a light source. The substrate has a first side. The light guide plate has a light exit surface and a light entry surface, wherein the light exit surface faces the first side of the substrate. The photosensors are disposed on the first side of the substrate. The light source is disposed near the light entry surface of the light guide plate, wherein light generated from the light source enters the light guide plate through the light entry surface. After entering the light guide plate, the light generated from the light source is incident to the substrate through the light exit surface of the light guide plate, or travels in the light guide plate by total internal reflection.

### CROSS REFERENCE TO RELATED APPLICATIONS

This application claims the benefit of U.S. provisional application No. 61/754,654, filed on Jan. 21, 2013, the contents of which are incorporated herein by reference.

### BACKGROUND OF THE INVENTION

1. Field of the Invention

The disclosed embodiments of the present invention relate to image sensing, and more particularly, to an image sensing apparatus which identifies/recognizes fingerprints by detecting reflected light.

2. Description of the Prior Art

Due to the advent of personal mobile devices (e.g. a smart phone), many users use their mobile devices to access services requiring user information (e.g. electronic transaction and membership control). In order to ensure the security of transaction, the service provider will confirm the user information (e.g. user name and password) provided by the client before providing related services. However, this kind of authentication may not identify a fraudulent use.

Thus, an authentication mechanism of high security is needed to protect user's rights.

### SUMMARY OF THE INVENTION

It is therefore one objective of the present invention to provide an image sensing apparatus for fingerprint recognition/identification/authentication to ensure the security of electronic transaction and protect user's rights.

It is therefore another objective of the present invention to provide a decoder circuit of an image sensing apparatus to reduce the number of traces required by the image sensing apparatus.

According to an embodiment of the present invention, an exemplary image sensing apparatus is disclosed. The exemplary image sensing apparatus comprises a substrate, a light guide plate, a plurality of photosensors and a light source. The substrate has a first side. The light guide plate has a light exit surface and a light entry surface, wherein the light exit surface faces the first side of the substrate. The photosensors are disposed on the first side of the substrate. The light source is disposed near the light entry surface of the light guide plate, wherein light generated from the light source enters the light guide plate through the light entry surface.

According to an embodiment of the present invention, an exemplary decoder circuit of an image sensing apparatus is disclosed. The image sensing apparatus comprises a photosensor array and a processing circuit. The photosensor array has a plurality of rows, a plurality of row control lines, a plurality of columns and a plurality of column data lines. The processing circuit has at least one input terminal and is arranged for processing a plurality of sensing signals of the column data lines. The exemplary decoder circuit comprises a control circuit and a column decoder circuit. The control circuit is arranged for generating at least one set of column selection signals, wherein each set of column selection signals comprises a plurality of column selection signals. The column decoder circuit is coupled to the control circuit, the processing circuit and the photosensor array, wherein the column decoder circuit couples the column data lines to the at least one input terminal according to the at least one set of column selection signals, and comprises at least one switch stage. The at least one switch stage is controlled by the at least one set of column selection signals, respectively, wherein the at least one switch stage has a plurality of input nodes and at least one output node, and couples the input nodes to the at least one output node according to the at least one set of column selection signals.

According to an embodiment of the present invention, an exemplary decoder circuit of an image sensing apparatus is disclosed. The image sensing apparatus comprises a photosensor array. The photosensor array has a plurality of rows, a plurality of row control lines, a plurality of columns and a plurality of column data lines. The exemplary decoder circuit comprises a control circuit and a row decoder circuit. The control circuit is arranged for generating a plurality of row control signals and at least one set of row selection signals, wherein the row control lines comprises a plurality of groups of row control lines; the row control signals are coupled to the groups of row control lines, respectively, and each set of row selection signals comprises a plurality of row selection signals. The row decoder circuit is coupled to the control circuit and the photosensor array, and comprises a plurality of switch circuits. The switch circuits are disposed in correspondence with the columns, respectively, wherein each switch circuit couples a plurality of photosensors of a column corresponding to the switch circuit to a column data line corresponding to the column according to the at least one set of row selection signals, and comprises at least one switch stage. The at least one switch stage is controlled by the at least one set of row selection signals, respectively, wherein the at least one switch stage has a plurality of input nodes and at least one output node, and couples the input nodes to the at least one output node according to the at least one set of row selection signals.

The proposed image sensing apparatus may sense an image of an object according to reflected light reflected from the object, and have different image sensing region based on different light paths. The proposed image sensing apparatus may be fabricated easily and have advantages of low cost and light weight. Additionally, the proposed decoder circuit of an image sensing apparatus may greatly reduce the number of traces required by the image sensing apparatus, thus not only saving cost but also reducing signal interferences to improve sensing quality. Further, the proposed image sensing apparatus may be employed in a mobile device capable of fingerprint identification to ensure the safety of electronic transaction and protect user's rights.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an exemplary image sensing apparatus according to an embodiment of the present invention.

FIG. 2 is an implementation of a partial architecture of the image sensing apparatus shown in FIG. 1.

FIG. 3 is an implementation of a partial architecture of the image sensing apparatus shown in FIG. 1.

FIG. 4 is an implementation of a partial architecture of the image sensing apparatus shown in FIG. 1.

FIG. 5 is an implementation of a partial architecture of the image sensing apparatus shown in FIG. 1.

FIG. 6 is an exemplary photosensor and a control circuit thereof according to an embodiment of the present invention.

FIG. 7 is an exemplary image sensing apparatus according to an embodiment of the present invention.

FIG. 8 is an exemplary image sensing apparatus according to an embodiment of the present invention.

FIG. 9 is an exemplary image sensing apparatus according to an embodiment of the present invention.

FIG. 10 is an exemplary image sensing apparatus according to an embodiment of the present invention.

FIG. 11 is an exemplary image sensing apparatus according to an embodiment of the present invention.

### DETAILED DESCRIPTION

When light meets a surface of an object, different light rays may reflect off the surface due to surface roughness. The proposed image sensing apparatus may identify an object image based on this principle. For example, as a fingerprint may have ridges and grooves, the proposed image sensing apparatus may be employed in fingerprint recognition/identification and/or fingerprint authentication. For the sake of brevity, an implementation of an exemplary fingerprint image sensing apparatus is described below. However, a person skilled in the art should understand that this is not meant to be a limitation of the present invention.

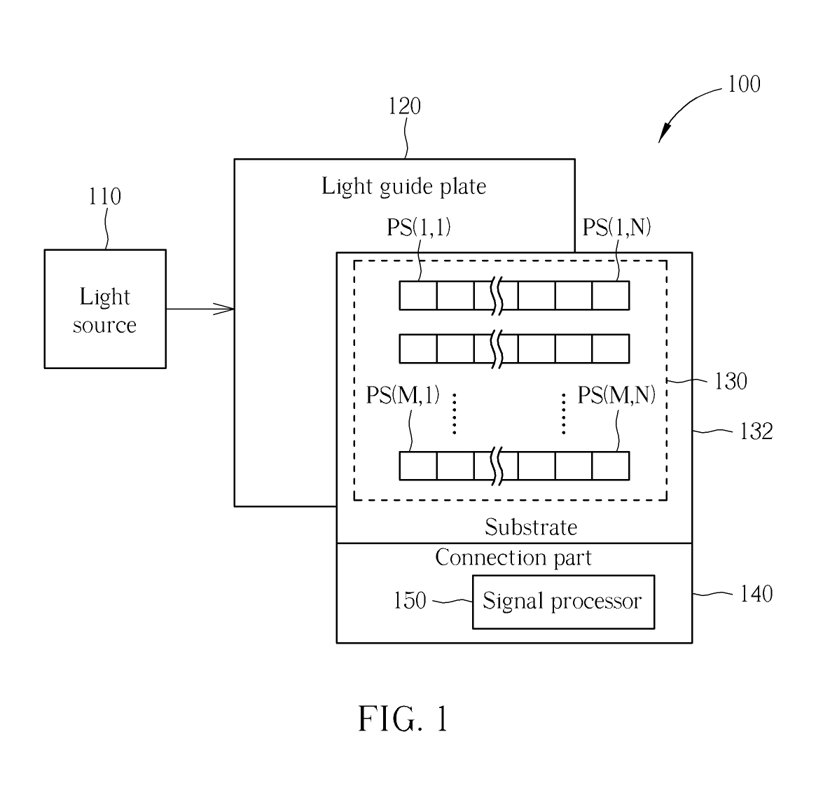

Please refer to FIG. 1, which is a diagram illustrating an exemplary image sensing apparatus according to an embodiment of the present invention. The image sensing apparatus 100 may be implemented as a fingerprint image sensing apparatus, and include a light source 110, a light guide plate 120, a substrate 132, a connection part 140 and a signal processor 150, wherein a photosensor array 130 is disposed on the substrate 132. The light guide plate 120 is disposed opposite to the substrate 132, and may guide light emitted from the light source 110. The photosensor array 130 may include a plurality of photosensors PS(1, 1)-PS(M, N) disposed on the substrate 132, wherein both M and N are positive integers, and the photosensors PS(1, 1)-PS(M, N) may be disposed between the light guide plate 120 and the substrate 132. The connection part 140 (e.g. a printed circuit board (PCB) or a flexible printed circuit board (FPCB)) is coupled between the photosensor array 130 and the signal processor 150, and is arranged to transmit sensing signals of the photosensor array 130 to the signal processor 150 for further processing. In an alternative design, a portion of the signal processor 150 (e.g. an analog-to-digital converter (ADC)) and the photosensor array 130 may be disposed on the same substrate 132 in order to reduce/eliminate transmission interference.

Depending on designs of light paths, the image sensing apparatus 100 may define the light guide plate 120 or the substrate 132 as a fingerprint identification region. In other words, one of the light guide plate 120 and the substrate 132 may have a contact surface, wherein when a finger touches the contact surface to generate reflected light, the reflected light may pass though the contact surface and falls on the photosensors PS(1, 1)-PS(M, N), and the photosensor array 130 may identify a fingerprint image accordingly. For example, in a case where a side of the substrate 132 which faces away from the light guide plate 120 (i.e. the side opposite to another side of the substrate 132 which faces the light guide plate 120) is defined as the fingerprint identification region (i.e. the contact surface), the light entering the light guide plate 120 may be guided to the photosensor array 130 (e.g. by crosstalk between the light guide plate 120 and the photosensor array 130). Hence, when the finger touches the side of the of the substrate 132 facing away from the light guide plate 120, the photosensor array 130 may identify the fingerprint image according to the reflected light reflected from the finger. Additionally, in a case a side of the light guide plate 120 which faces away from the substrate 132 (i.e. the side opposite to another side of the light guide plate 120 which faces the substrate 132) is defined as the fingerprint identification region (i.e. the contact surface), the light entering the light guide plate 120 may be substantially confined within the light guide plate 120 (e.g. the light travels by total internal reflection). When the finger touches the side of the light guide plate 120 facing away from the substrate 132, the confinement fails (e.g. frustrated total internal reflection (FTIR)) and the photosensor array 130 may identify the fingerprint image according to the reflected light reflected from the finger. First, an implementation of an exemplary image sensing apparatus which defines a side of a substrate as a fingerprint identification region is described below.

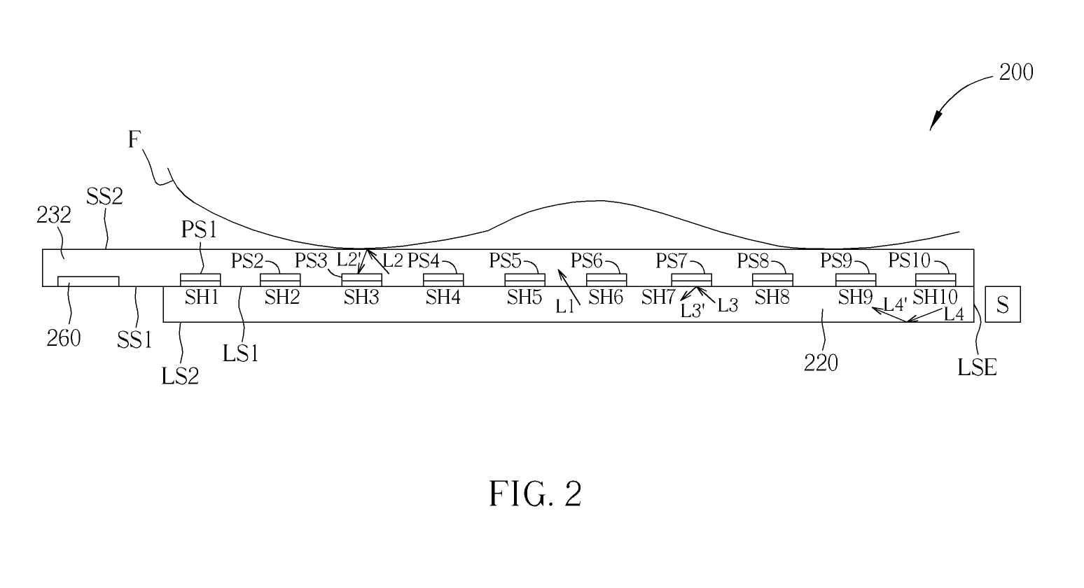

Please refer to FIG. 2, which is an implementation of a partial architecture of the image sensing apparatus 100 shown in FIG. 1. The image sensing apparatus 200 shown in FIG. 2 may include a substrate 232, a plurality of photosensors PS1-PS10, a light guide plate 220 and a source S. The substrate 232 has a first side SS1 and a second side SS2, wherein the photosensors PS1-PS10 are disposed on the first side SS1 of the substrate 232. Please note that the photosensors PS1-PS10 and a corresponding substrate area may be regarded as a portion of a photosensor array (e.g. the photosensor array 130 shown in FIG. 1).

The light guide plate 220 may have a first surface LS1, a second surface LS2 opposite to the first surface LS1, and a lateral side LSE. The light source S is disposed near the lateral side LSE of the light guide plate 220 (e.g. disposed in correspondence with the lateral side LSE) so that light generated from the light source S may enter the light guide plate 220 through the lateral side LSE. In other words, the lateral side LSE is a light entry surface of the light guide plate 220. For example, the light source S may be implemented by an infrared (IR) light emitter and disposed on the lateral side LSE. As shown in FIG. 2, the first surface LS1 may abut against the first side SS1 of the substrate 232. Hence, after entering the light guide plate 220, the light generated from the light source S may fall on the substrate 232 through the first surface LS1 (e.g. light L1). To put is differently, the light in the light guide plate 220 may travel toward the substrate 232 due to crosstalk between the light guide plate 220 and the substrate 232, wherein the first surface LS1 may be regarded as a light exit surface of the light guide plate 220.

The substrate 232 may have transparency so that the light from the light guide plate 220 may travel therein. When an object (e.g. a user's finger F) touches the second side SS2 of the substrate 232 (e.g. a contact surface for fingerprint identification) and reflect light in the substrate 232 (e.g. light L2), the photosensors PS1-PS10 may receive reflected light reflected from the finger F (e.g. light L2′) to detect an image of the finger F (e.g. identifying ridges of the finger F). In practice, the substrate 232 may be a glass substrate or other substrate having transparency, and the photosensor array corresponding to the photosensors PS1-PS10 may be an amorphous, single-crystalline or polysilicon photosensor array. As the glass substrate has advantages of thin thickness and low cost, the proposed image sensing apparatus is very suitable for use in person mobile apparatuses when the glass substrate is used as the substrate 232.

In order to ensure the light received by the photosensors PS1-PS10 is from the light reflected from the finger F rather than the light traveling in the light guide plate 220, the image sensing apparatus 200 may further include a plurality of light shielding devices SH1-SH10, which are disposed respectively in correspondence with the photosensors (i.e. each shielding device is disposed at a side of a corresponding photosensor facing the first surface LS1) in order to prevent the light generated from the light source S from falling on the photosensors PS1-PS10 directly (e.g. light L3 and light L3′). Hence, the light entering the light guide plate 220 is ensured to travel toward the substrate 232 through a region where the first surface LS1 abuts against the first side SS1 (i.e. the region where no light shielding device is disposed).

It should be noted that, as the light generated from the light source S enters the light guide plate 220 from the lateral side LSE, the light in the light guide plate 220 may fall on the second surface LS2 at a larger angle. When a refractive index of a medium inside the light guide plate 220 is higher than a refractive index of a medium outside the light guide plate 220, the light in the light guide plate 220 may travel by total internal reflection (e.g. light L4 falling on the second surface LS2 and reflected light L4′ thereof). Hence, after entering the light guide plate 220, the light generated from the light source S may distribute uniformly in the light guide plate 220 rather than pass out of the second surface LS2, thus reducing power dissipation.

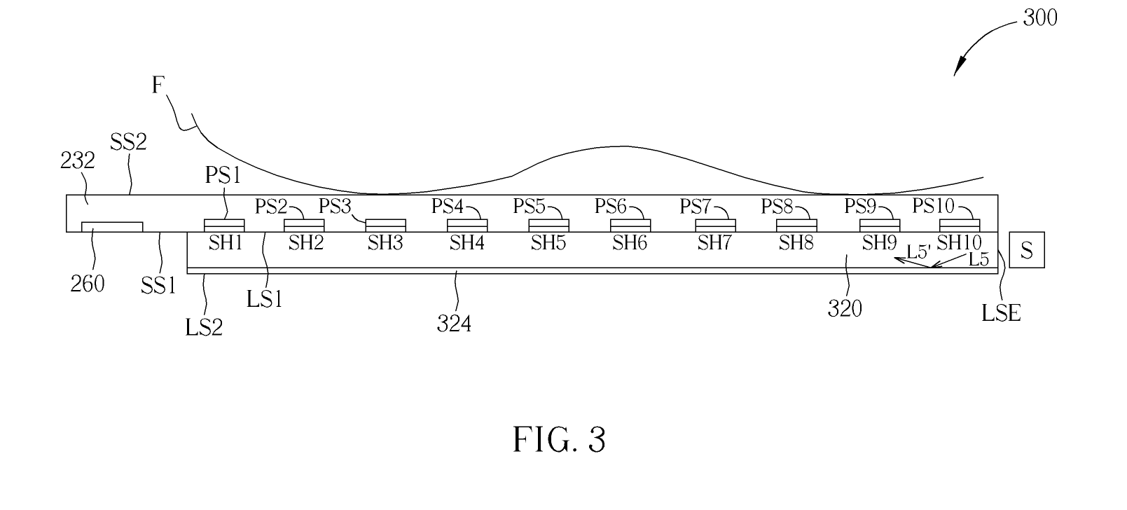

In alternative design, a microstructure may be disposed in the light guide plate to ensure that the light travels in light guide plate instead of dissipating from the light guide plate. Please refer to FIG. 3, which is an implementation of a partial architecture of the image sensing apparatus 100 shown in FIG. 1. The architecture of the image sensing apparatus 300 shown in FIG. 3 is based on that of the image sensing apparatus 200 shown in FIG. 2, wherein the main difference is that a light guide plate 320 included in the image sensing apparatus 300 may include a microstructure 324 (e.g. a dot pattern microstructure), which may be disposed on the second surface LS2 and in the light guide plate 320. The microstructure 324 may change a travel path of the light generated from the light source S in the light guide plate 320 (e.g. light L5 and light L5′), thus ensuring the light generated from the light source S to fall on the substrate 232. As a person skill in the art should understand the operations of using an optical microstructure to change a light path, further description is omitted here for brevity.

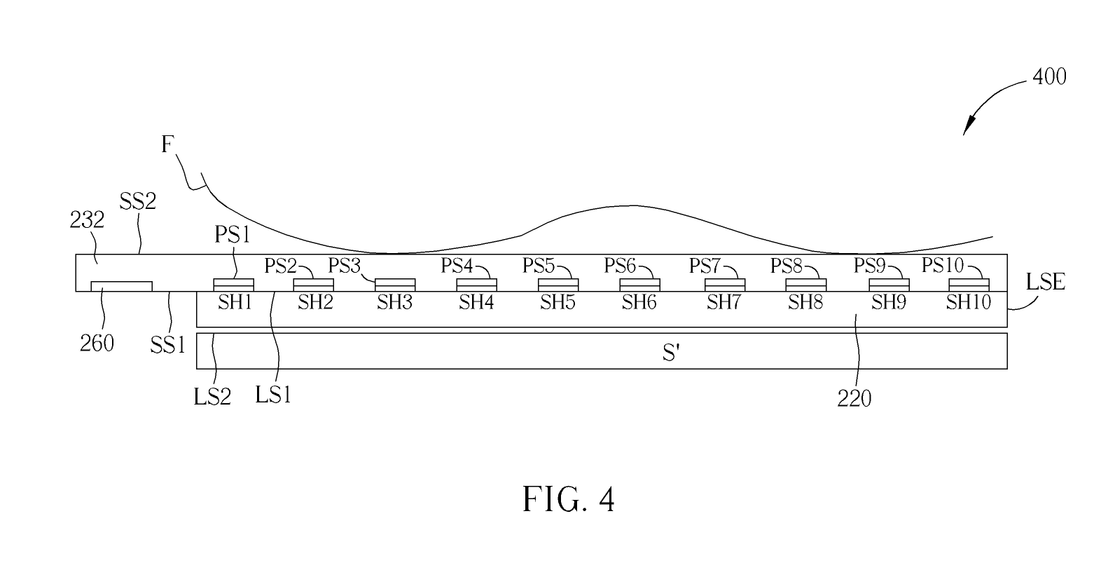

Please refer to FIG. 4, which is an implementation of a partial architecture of the image sensing apparatus 100 shown in FIG. 1. The architecture of the image sensing apparatus 400 shown in FIG. 4 is based on that of the image sensing apparatus 200 shown in FIG. 2, wherein the main difference is that a light source S′ of the image sensing apparatus 400 may be disposed near the second surface LS2 of the light guide plate 220 (e.g. disposed in correspondence with the second surface LS2). Hence, light generated from the light source S′ may enter the light guide plate 220 through the second surface LS2 (e.g. the second surface LS2 is the light entry surface of the light guide plate 220). In practice, the light source S′ may be implemented by a surface light source (or a plane light source) and disposed on the second surface LS2. As a person skill in the art should understand the operations of the image sensing apparatus 400 after reading the paragraphs directed to FIG. 1-FIG. 3, further description is omitted here for brevity.

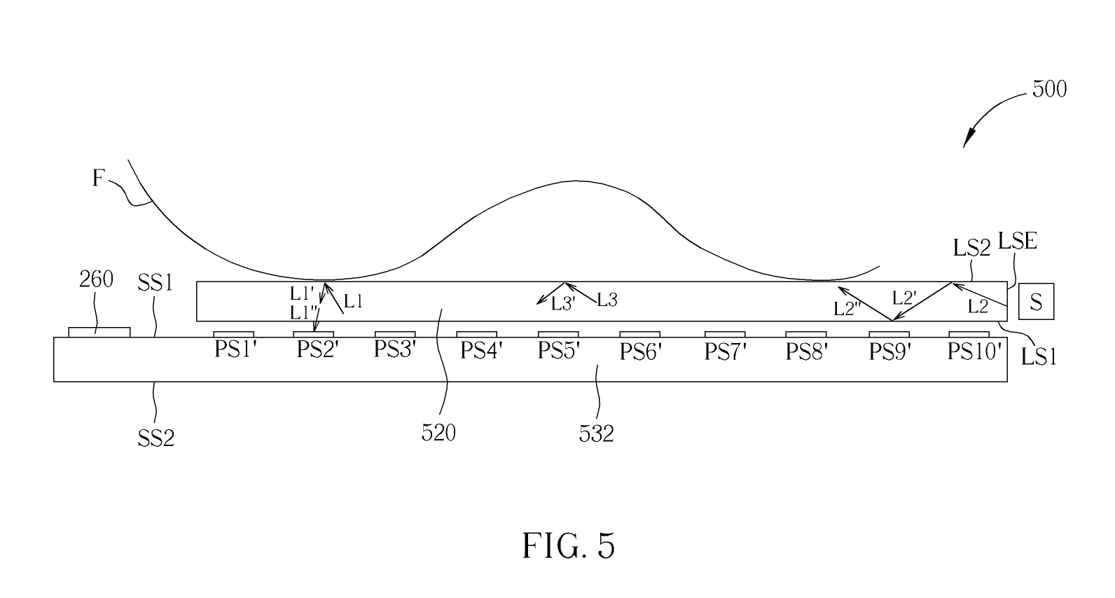

An implementation of an exemplary image sensing apparatus which defines a side of a light guide plate a fingerprint identification region is described below. Please refer to FIG. 5, which is an implementation of a partial architecture of the image sensing apparatus 100 shown in FIG. 1. As shown in FIG. 5, the image sensing apparatus 500 may include a substrate 532, a light guide plate 520, a light source S and a plurality of photosensors PS1′-PS10′. The substrate 532 has a first side SS1 and a second side SS2. The light guide plate 520 has a first surface LS1, a second surface LS2 opposite to the first surface LS1, and a lateral side LSE, wherein the first surface LS1 is disposed in correspondence with the substrate 532. The light source S is disposed near the lateral side LSE of the light guide plate 520 (e.g. disposed in correspondence with the lateral side LSE), wherein light generated from the light source S may enter the light guide plate 520 though the lateral side LSE. The photosensors PS1′-PS10′ are disposed on the first side SS1 of the substrate 532, and does not touch the first surface LS1. When an object (e.g. a user's finger F) touches the second surface LS2 of the light guide plate 520 (e.g. a contact surface for fingerprint identification) to reflect light in the light guide plate 520 (e.g. light L1), the photosensors PS1′-PS10′ may receive reflected light reflected from the finger F (e.g. light L1′) to detect an image of the finger F (e.g. identifying ridges of the finger F).

In one implementation, frustrated total internal reflection may be utilized to ensure the light received by the photosensors PS1′-PS10′ is from the light reflected from the finger F. Specifically, as the light generated from the light source S enters the light guide plate 520 from the lateral side LSE, the light in the light guide plate 520 may fall on the first surface LS1 and/or the second surface LS2 at a larger angle. When a refractive index of a medium inside the light guide plate 520 is higher than a refractive index of a medium outside the light guide plate 520, the light in the light guide plate 520 may travel by total internal reflection (e.g. light L2 falling on the second surface LS2 and reflected light L2′ thereof, and light L2″ reflected from the first surface LS1).

When a ridge of the finger F touches the second surface LS2 of the light guide plate 520, total internal reflection is destroyed in a touched area. The light in the light guide plate 520 may be reflected by the finger F (e.g. the light L1 and the light L1′), and the reflected light may pass through the first surface LS1 toward a photosensor (e.g. light L1″). The photosensor (e.g. the photosensor PS2′) may detect the image of the finger F accordingly. Regarding untouched area (s) on the second surface LS2, the light may still travel in the light guide plate 520 by total internal reflection (e.g. light L3 and light L3′). Hence, photosensor(s) corresponding to groove(s) of the finger F (e.g. the photosensor PS5′) may not receive reflected signal(s).

In this implementation, the medium outside the light guide plate 520 may be air (i.e. the substrate 532 and the first surface LS1 are separated by air). Hence, the refractive index of the medium outside the light guide plate 520 is less than the refractive index of the medium inside the light guide plate 520, allowing the light generated from the light source S to travel in the light guide plate 520 by total internal reflection. In alternative design, the medium between the substrate 532 and the first surface LS1 may be another medium other than air. As long as the refractive index of the medium located between the substrate 532 and the first surface LS1 is higher than the refractive index of the light guide plate 520, the light generated from the light source S may travel in the light guide plate 520 by total internal reflection, thus allowing the use of frustrated total internal reflection to identify fingerprints.

Please note that the substrate 532 may be a glass substrate, and a photosensor array corresponding to the photosensors PS1′-PS10′ may be an amorphous, single-crystalline or polysilicon photosensor array. Hence, the requirements of thin thickness and low cost can be met.

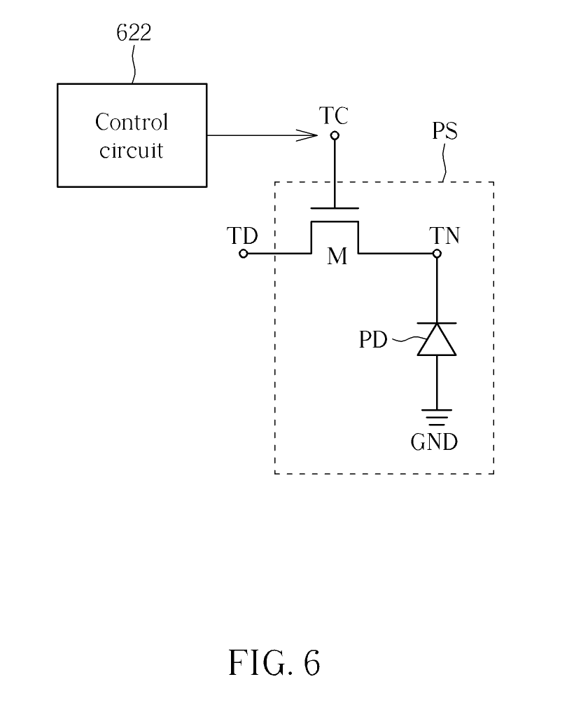

In the implementations shown in FIG. 2-FIG. 5, a peripheral circuit 260 may be disposed on the substrate 232/532 and arranged to control devices included in the image sensing apparatus. Please refer to FIG. 6, which is an exemplary photosensor and a control circuit thereof according to an embodiment of the present invention. A control circuit 622 may be used to implement at least a portion of the peripheral circuit 260 shown in FIG. 2-FIG. 5, and a photosensor PS may be used to implement at least one of the photosensors PS1-PS10 shown in FIG. 2-FIG. 4 and/or at least one of the photosensors PS1′-PS10′ shown in FIG. 5. The control circuit 622 is coupled to a control terminal TC of the photosensor PS, and is arranged for controlling a sensing signal of the photosensor PS to be outputted from a data terminal TD of the photosensor PS. By way of example, but not limitation, the photosensor PS may include transistor M and a photodiode PD. The transistor has the control terminal TC, a connection terminal TN and the data terminal TD. The photodiode PD is coupled between the connection terminal TN and ground GND, and is arranged for receiving reflected light (e.g. the light L2′ shown in FIG. 2 or the light L1″ shown in FIG. 5) generated in response to a touch of an object (e.g. the finger F shown in FIG. 2-FIG. 5) on a light guide plate or a substrate, and accordingly generating a sensing signal to the connection terminal TN. The control circuit 622 is coupled to the control terminal TC of the transistor M, and is arranged for controlling the transistor M to output a corresponding sensing signal from the data terminal TD of the transistor M.

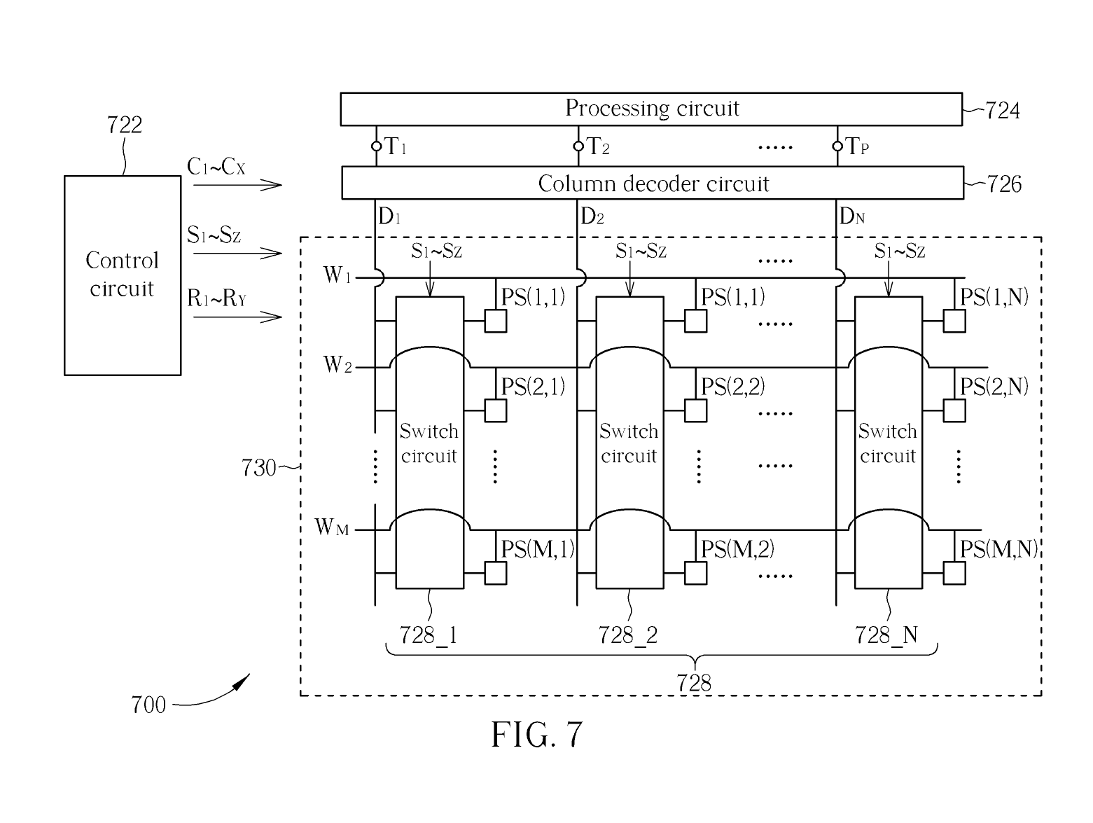

In one implementation, the peripheral circuit 260 shown in FIG. 2-FIG. 5 may process the generated sensing signal of the photosensor. Please refer to FIG. 7, which is an exemplary image sensing apparatus according to an embodiment of the present invention. The image sensing apparatus 700 may employ one of the architectures of the image sensing apparatuses 200-500 shown in FIG. 2-FIG. 5. The image sensing apparatus 700 may include, but is not limited to, a control circuit 722, a processing circuit 724, a column decoder circuit 726, a row decoder circuit 728 and a photosensor array 730, wherein a plurality of photosensors PS(1, 1)-PS(M, N) of the photosensor array 730 may employ the architecture of the photosensor PS shown in FIG. 6. Additionally, the photosensor array 730 may have a plurality of rows (corresponding to the photosensors PS(1, 1)-PS(1, N), PS(2, 1)-PS(2, N), . . . , PS(M, 1)-PS(M, N), respectively), a plurality of columns (corresponding to the photosensors PS(1, 1)-PS(1, N), PS(2, 1)-PS(2, N), . . . , PS(M, 1)-PS(M, N), respectively), a plurality of row control lines W₁-W_{M} and a plurality of column data lines D₁-D_{N}, wherein photosensors corresponding to the same row are electrically connected to the same row control line, and photosensors corresponding to the same column are electrically connected to the same column data line.

The control circuit 722, the processing circuit 724, the column decoder circuit 726, the row decoder circuit 728 may be used to implement at least a portion of the peripheral circuit 260 shown in FIG. 2-FIG. 5. The control circuit 722 may generate a plurality of column selection signals C₁-C_{X}, a plurality of row control signals R₁-R_{Y} and a plurality of row selection signals S₁-S_{Z}, and enable the photosensors of the rows according to the row control signals R₁-R_{Y}. The column decoder circuit 726 is coupled to the control circuit 722, the processing circuit 724 and the photosensor array 730, and is operative for coupling the column data lines D₁-D_{N} to a plurality of input terminals T₁-T_{P} of the processing circuit 724 according to the column selection signals C₁-C_{X}. By way of example, but not limitation, the column data lines D₁-D_{N} may be divided into a plurality of groups of column data lines (corresponding to the input terminals T₁-T_{P}, respectively), wherein each group of column data lines may have a plurality of column data lines, and transmits sensing signals thereof to a corresponding input terminal according to the column selection signals C₁-C_{X}.

The row decoder circuit 728 is coupled to the control circuit 722 and the photosensor array 730, and may include a plurality of switch circuits 728_{—}1-728_N. The switch circuits 728_{—}1-728_N are disposed in correspondence with the columns of the photosensor array 730 (i.e. the column data lines D₁-D_{N}), respectively, wherein each switch circuit may couple photosensors coupled to the switch circuit to a column data line corresponding to the switch circuit according to the row selection signals S₁-S_{Z}, thereby transmitting sensing signals of the photosensors to the column data line. By way of example, but not limitation, the row control lines W₁-W_{M} may be divided into a plurality of groups of row control lines (corresponding to row control signals R₁-R_{Y}, respectively), wherein each group of row control lines may have a plurality of row control lines. Regarding a switch circuit, photosensors coupled to each group of row control lines may be coupled to a column data line corresponding to the switch circuit according to the row selection signals S₁-S_{Z}. Additionally, the processing circuit 724 may process sensing signals of the column data lines D₁-D_{N} to obtain an image of an object to be detected (e.g. a fingerprint image).

As shown in FIG. 7, the photosensor array 730 may need (M+N) signal traces at least. The number of traces required by the image sensing apparatus 700 may be greatly reduced by the use of the column decoder circuit 726 and/or the row decoder circuit 728. An implementation of an image sensing apparatus having a column decoder circuit is described below.

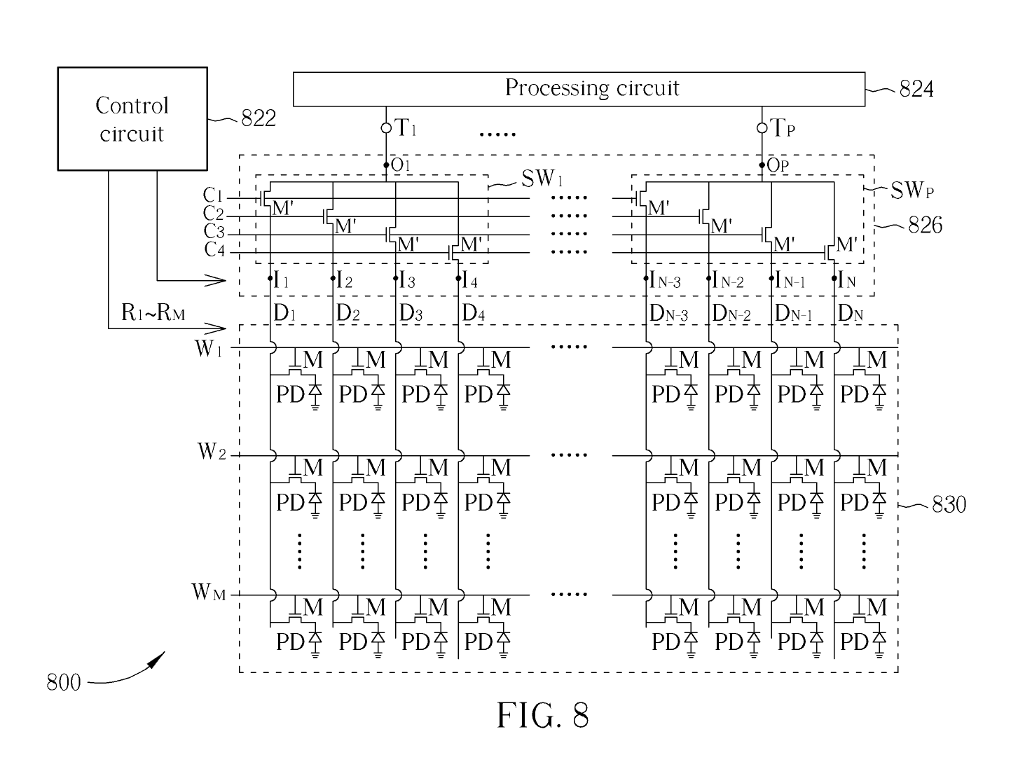

Please refer to FIG. 8, which is an exemplary image sensing apparatus according to an embodiment of the present invention. The image sensing apparatus 800 may include a control circuit 822, a processing circuit 824, a column decoder circuit 826 and a photosensor array 830, wherein the control circuit 722, the processing circuit 724, the column decoder circuit 726 and the photosensor array 730 shown in FIG. 7 may be implemented by the control circuit 822, the processing circuit 824, the column decoder circuit 826 and the photosensor array 830, respectively. In this embodiment, a plurality of photosensors included in the photosensor array 830 may employ the architecture of the photosensor PS shown in FIG. 6, wherein each photosensor may include the transistor M and the photodiode PD. The control circuit 822 may generate a plurality of row control signals R₁-R_{M} to control the photosensors of a plurality of row control lines W₁-W_{M}, respectively.

The control circuit 822 may further generate a set of column selection signals C₁-C₄ for column decoding operations. The column decoder circuit 826 may include a plurality of sets of switches SW₁-SW_{P}, wherein the sets of switches SW₁-SW_{P} are coupled in parallel between the processing circuit 824 and the photosensor array 830. Each set of switches may include a plurality of input nodes and an output node, and couple one of the input nodes to the output node according to a corresponding set of column selection signals. For example, the set of switches SW₁ may couple one of input nodes I₁-I₄ to an output node O₁ according to the set of column selection signals C₁-C₄, and the set of switches SW_{P} may couple one of input nodes I_{N-3}-I_{N} to an output node O_{P} according to the set of column selection signals C₁-C₄.

In this embodiment, each set of switches may include a plurality of switches, wherein each switch may be implemented by a transistor M′. switches of each set of switches may couple one of input nodes of the set of switches to an output node of the set of switches according to the set of column selection signals C₁-C₄, respectively, thereby outputting sensing signals of corresponding column data lines to the processing circuit 822. For example, when the control circuit 822 enables the row control line W₁ and the column selection signal C₁ is at a specific level (e.g. a high level), sensing signals of column data lines, which correspond to (i.e. enabled by) the column selection signal C₁, of rows corresponding to (i.e. enabled by) the row control line W₁ may be outputted to the processing circuit 824.

As the input nodes I₁-I_{N} are coupled to the column data lines D₁-D_{N}, respectively, and the output nodes O₁-O_{P} are coupled to the input terminals T₁-T_{P} of the processing circuit 824, respectively, the number of traces connected to the processing circuit 824 may be decreased from N to P. For example, if the photosensor array 830 has 240 column data lines (i.e. N equals 240), using the column decoder circuit 826 may reduce the number of traces from 240 to 64, wherein 60 traces are signal traces connected to the processing circuit 824, and 4 traces are signal traces of the set of column selection signals C₁-C₄.

The processing circuit 824 may include at least one analog-to-digital converter (not shown in FIG. 8), which may be used to process the sensing signals transmitted to the input terminals T₁-T_{P}. In a case where the sensing signals of the column data lines D₁-D_{N} are transmitted in series, the processing circuit 824 may include a single analog-to-digital converter; in a case where the sensing signals of the column data lines D₁-D_{N} are transmitted in parallel, the processing circuit 824 may include a plurality of analog-to-digital converters to process the sensing signals received by the input terminals T₁-T_{P} concurrently.

Please note that the number of column selection signals and/or the number of sets of switches shown in FIG. 8 is for illustrative purposes only, and is not meant to be a limitation of the present invention. In other words, the number of column selection signals and/or the number of sets of switches may be adjusted according to actual requirements/considerations.

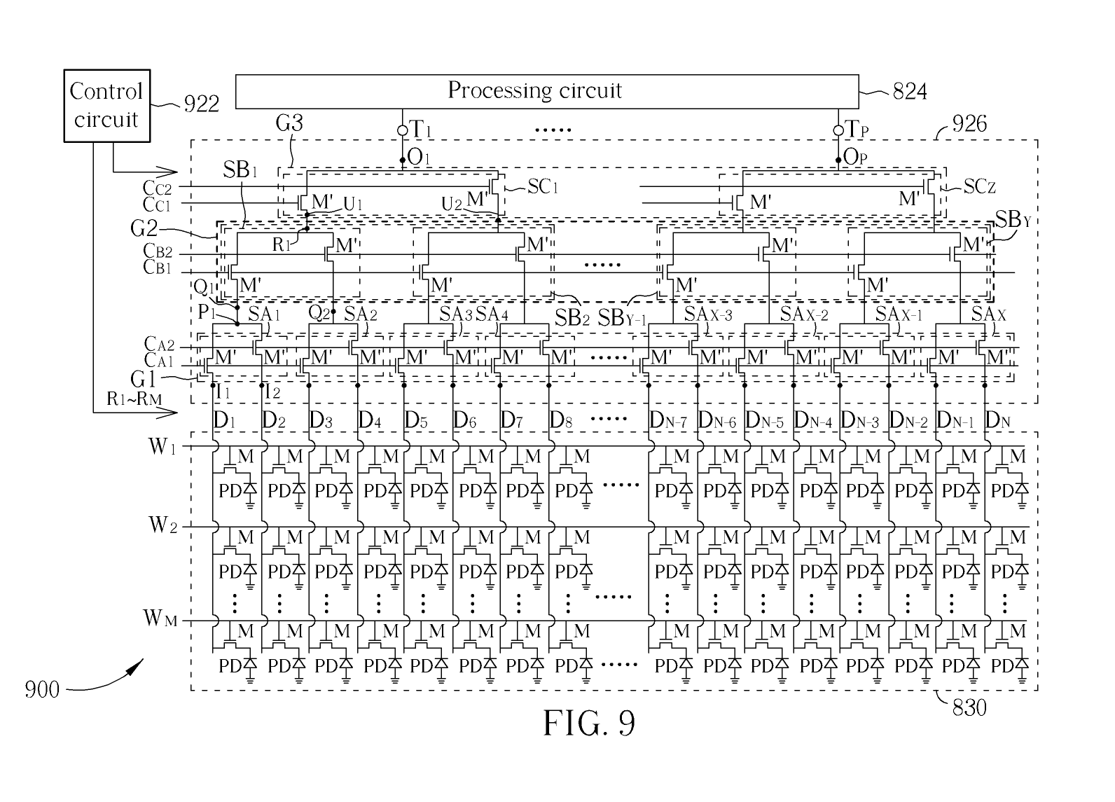

Please refer to FIG. 9, which is an exemplary image sensing apparatus according to an embodiment of the present invention. The image sensing apparatus 900 may include a control circuit 922, a column decoder circuit 926, and the processing circuit 824 and the photosensor array 830 shown in FIG. 8, wherein the control circuit 722 and the column decoder circuit 726 shown in FIG. 7 may be implemented by the control circuit 922 and the column decoder circuit 926. The control circuit 922 may generate a plurality of row control signals R₁-R_{M} to control photosensors of the row control lines W₁-W_{M}, respectively, and generate a plurality of sets of column selection signals C_{A1}-C_{A2}, C_{B1}-C_{B2} and C_{C1}-C_{C2} for column decoding operations. The column decoder circuit 926 may include a plurality of switch stages G₁-G₃ coupled in series, wherein the switch stages G₁-G₃ may be controlled by the sets of column selection signals C_{A1}-C_{A2}, C_{B1}-C_{B2} and C_{C1}-C_{C2}, respectively. Hence, the column decoder circuit 926 may couple the column data lines D₁-D_{N} to the input terminals T₁-T_{P} of the processing circuit 824 according to the sets of column selection signals C_{A1}-C_{A2}, C_{B1}-C_{B2} and C_{C1}-C_{C2}.

As shown in FIG. 9, as the switch stage G₁ is adjacent to the photosensor array 830, input nodes of the switch stage G₁ may be coupled to the column data lines D₁-D_{N}, respectively; as the switch stage G₃ is adjacent to the processing circuit 824, output nodes of the switch stage G₃ may be coupled to the input terminals T₁-T_{P}, respectively. Further, as the switch stage G₂ is coupled in series between the switch stage G₁ and the switch stage G₃, input nodes of the switch stage G₂ may be coupled to output nodes of the switch stage G₁, respectively, and output nodes of the switch stage G₂ may be coupled to input nodes of the switch stage G₃, respectively.

In this embodiment, the switch stages G₁-G₃ may include a plurality sets of switches SA₁-SA_{X}, SB₁-SB_{Y} and SC₁-SC_{Z}, wherein each set of switches may have a plurality of input nodes and an output node, and couple one of the input nodes to the output node according to a set of column selection signals of a corresponding switch stage, thereby outputting a sensing signal of a corresponding column data line to a next stage. In practice, each set of switches may include a plurality of switches (e.g. the transistor M′), and the switches may couple one of input nodes of the set of switches to an output node of the set of switches according to a set of column selection signals of a corresponding switch stage.

For example, the set of switches SA₁ may couple one of input nodes I₁-I₂ to an output node P₁ according to the set of column selection signals C_{A1}-C_{A2}, the set of switches SB₁ may couple one of input nodes Q₁-Q₂ to an output node R₁ according to the set of column selection signals C_{B1} C_{B2}, and the set of switches SC₁ may couple one of the nodes U₁-U₂ to an output node Q₁ according to the set of column selection signals C_{C1}-C_{C2}. Hence, when the control circuit 822 enables the row control line W₁ and each of the column selection signals C_{A1}, C_{B1} and C_{C1} is at a specific level (e.g. a high level), the sensing signal of the column data line D₁ may be outputted to the processing circuit 824.

Please note that the column decoder circuit 826 shown in FIG. 8 may be regarded as a decoder circuit having a single switch stage (corresponding to the set of switches SW₁-SW_{P}). As the number of traces may be greatly decreased when only one switch stage is disposed in the column decoder circuit 826, the decoder architecture of the switch stages coupled in series shown in FIG. 9 may further reduce the number of traces. For example, if the photosensor array 830 has 240 column data lines (i.e. N equals 240), using the column decoder circuit 926 may reduce the number of traces from 240 to 36, wherein 30 traces are signal traces connected to the processing circuit 824, and 6 traces are signal traces of the set of column selection signals C_{A1}-C_{A2} C_{B1}-C_{B2} and C_{C1}-C_{C2}.

Please note that the number of column selection signals and/or the number of sets of switches shown in FIG. 9 is for illustrative purposes only, and is not meant to be a limitation of the present invention. In one implementation, the switch stage adjacent to the processing circuit may have only one set of switches, and the processing circuit may have only one input terminal. Additionally, one column selection signal of each set of column selection signals may be an inverting signal of another column selection signal thereof (e.g. column selection signal C_{A1} and the column selection signal C_{A2}).

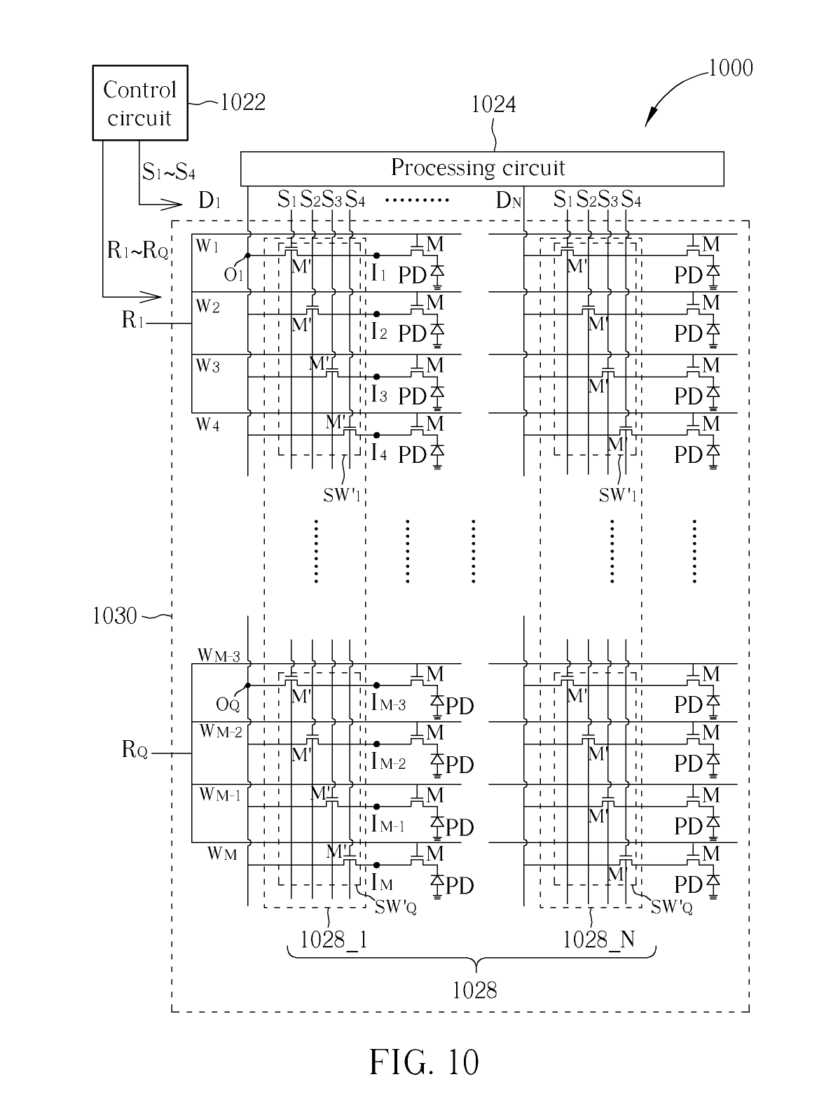

The row decoder circuit may be utilized to reduce the number of traces required by the image sensing apparatus. Please refer to FIG. 10, which is an exemplary image sensing apparatus according to an embodiment of the present invention. The image sensing apparatus 1000 may include a control circuit 1022, a processing circuit 1024, a row decoder circuit 1028 and a photosensor array 1030, wherein the control circuit 722, the processing circuit 724, the row decoder circuit 728 and the photosensor array 730 shown in FIG. 7 may be implemented by the control circuit 1022, the processing circuit 1024, the row decoder circuit 1028 and the photosensor array 1030. In this embodiment, a plurality of photosensors included in the photosensor array 1030 may employ the architecture of the photosensor PS shown in FIG. 6, wherein each photosensor may include the transistor M and the photodiode PD.

The control circuit 1022 may generate a plurality of row control signals R₁-R_{Q} and a set of row selection signals S₁-S₄, wherein a plurality of row control lines W₁-W_{M} may be regarded as a plurality of groups of row control lines, and the groups of row control lines W₁-W_{M} are coupled to the row control signals R₁-R_{Q}, respectively (e.g. the row control lines W₁-W₄ may be regarded as a set of row control lines coupled to the row control signal R₁). The row decoder circuit 1028 may include a plurality of switch circuits 1028_{—}1-1028_N, which are disposed in correspondence with a plurality of columns of the photosensor array 1030, respectively. Each switch circuit may couple photosensors of a column corresponding to the switch circuit to a column data line corresponding to the column according to the set of row selection signals S₁-S₄.

In this embodiment, each switch circuit may include a plurality of sets of switches SW′₁-SW′_{Q}, wherein the sets of switches SW′₁-SW′_{Q} are coupled in parallel between a column corresponding to the switch circuit and a column data line corresponding to the column. Each set of switches may include a plurality of input nodes and an output node, and couple one of the input nodes to the output node according a corresponding set of row selection signals. For example, the set of switches SW′₁ may couple one of input nodes I₁-I₄ to an output node O₁ according the set of row selection signals S₁-S₄. Additionally, all of input nodes I₁-I_{M} of the sets of switches SW′₁-SW′_{Q} are coupled to photosensors of a corresponding column, respectively, and all of output nodes O₁-O_{Q} are coupled to a column data line corresponding to the column.

Each set of switches may include a plurality of switches, wherein each switch may be implemented by the transistor M′. The switches of each set of switches may couple one of input nodes of the set of switches to an output node of the set of switches according to the row selection signals S₁-S₄, respectively, thereby outputting sensing signals to a corresponding column data line. For example, when each of the row control signal R₁ and the row selection signal S₁ is at a specific level (e.g. a high level), sensing signals of photosensors, which correspond to (i.e. enabled by) the row selection signal S₁, of the row control lines W₁-W₄ may be outputted to the column data lines D₁-D_{N}.

As the row control lines W₁-W_{M} are coupled to the row control signals R₁-R_{Q}, respectively, the number of traces connected to the control circuit 1022 may be decreased from M to Q. For example, if the photosensor array 1030 has 240 row control lines (i.e. M equals 240), using the row decoder circuit 1028 may reduce the number of traces from 240 to 64, wherein 60 traces are signal traces connected to the control circuit 1022, and 4 traces are signal traces of the set of row selection signals S₁-S₄.

Please note that the number of row selection signals and/or the number of sets of switches shown in FIG. 10 is for illustrative purposes only, and is not meant to be a limitation of the present invention. In other words, the number of row selection signals and/or the number of sets of switches may be adjusted according to actual requirements/considerations.

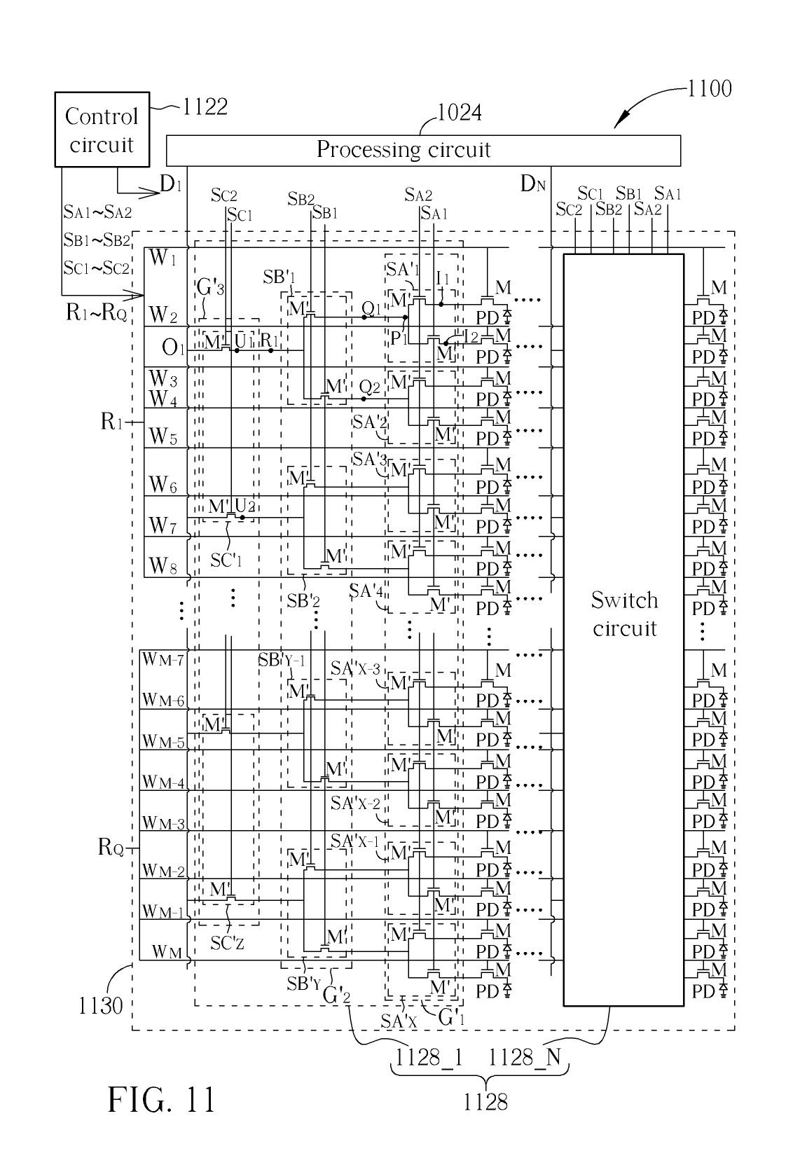

Please refer to FIG. 11, which is an exemplary image sensing apparatus according to an embodiment of the present invention. The image sensing apparatus 1100 may include a control circuit 1122, a row decoder circuit 1128, a photosensor array 1130 and the processing circuit 1024 shown in FIG. 10, wherein the control circuit 722, the row decoder circuit 728 and the photosensor array 730 shown in FIG. 7 may be implemented by the control circuit 1122, the row decoder circuit 1128 and the photosensor array 1130. In this embodiment, a plurality of photosensors included in the photosensor array 1130 may employ the architecture of the photosensor PS shown in FIG. 6, wherein each photosensor may include the transistor M and the photodiode PD.

The control circuit 1122 may generate a plurality of row control signals R₁-R_{Q} and a set of row selection signals S_{A1}-S_{A2}, S_{B1}-S_{B2} and S_{C1}-S_{C2}, wherein a plurality of row control lines W₁-W_{M} may be regarded as a plurality of groups of row control lines, and the groups of row control lines W₁-W_{M} are coupled to the row control signals R₁-R_{Q}, respectively. The row decoder circuit 1128 may include a plurality of switch circuits 1128_{—}1-1128_N, which are disposed in correspondence with a plurality of columns of the photosensor array 1130, respectively. In this embodiment, each switch circuit may have an identical topology (e.g. the topology of the switch circuit 1128_{—}1). However, this is for illustrative purposes only, and is not meant to be a limitation of the present invention.

As show in FIG. 11, each switch circuit may include a plurality of switch stages G′₁-G′₃ coupled in series, wherein the switch stages G′₁-G′₃ are controlled by the sets of row selection signals S_{A1}-S_{A2}, S_{B1}-S_{B2} and S_{C1}-S_{C2}, respectively. Hence, the switch circuit may couple photosensors of a column corresponding to the switch circuit to a column data line corresponding to the column according to the sets of row selection signals S_{A1}-S_{A2}, S_{B1}-S₃₂ and S_{C1}-S_{C2}.

As the switch stage the switch stage G′₁ is adjacent to respective photosensors corresponding to switch circuits 1128_{—}1-1128_N, input nodes of the switch stage G′₁ may be coupled to the photosensors corresponding to each switch circuit, respectively; as the switch stage G′₃ is adjacent to respective column data lines corresponding to switch circuits 1128_{—}1-1128_N, output nodes of the switch stage G′₃ may be coupled to a column data line corresponding to each switch circuit. Further, as the switch stage G′₂ is coupled in series between the switch stage G′₁ and the switch stage G′₃, input nodes of the switch stage G′₂ may be coupled to output nodes of the switch stage G′₁, respectively, and output nodes of the switch stage G′₂ may be coupled to input nodes of the switch stage G′₃, respectively.

In this embodiment, the switch stages G₁-G₃ may include a plurality of sets of switches SA′₁-SA′_{X}, SB′₁-SB′_{Y} and SC′₁-SC′_{Z}, wherein each set of switches may have a plurality of input nodes and an output node, and couple one of the input nodes to the output node according a set of row selection signal of a corresponding switch stage, thereby outputting a sensing signal of a corresponding photosensor to a next stage. In practice, each set of switches may include a plurality of switches (e.g. the transistor M′), and the switches may couple one of input nodes of the set of switches to an output node of the set of switches according to a set of row selection signals of a corresponding switch stage.

For example, the set of switches SA′₁ may couple one of input nodes I₁-I₂ to an output node P₁ according to the set of row selection signals S_{A1}-S_{A2}, the set of switches SB′₁ may couple one of input nodes Q₁-Q₂ to an output node R₁ according to the set of row selection signals S_{B1}-S_{B2}, and the set of switches SC′₁ may couple one of input nodes U₁-U₂ to an output node O₁ according to the set of row selection signals S_{C1}-S_{c2}. Hence, when each of the row control signal R₁ and the row selection signals S_{A1}, S_{B1} and S_{C1} is at a specific level (e.g. a high level), sensing signals of photosensors corresponding to (i.e. enabled by) the row control line W₁ may be outputted to the column data lines D₁-D_{N}.

Please note that each switch circuit shown in FIG. 10 may be regarded as a decoder circuit including a single switch stage (corresponding to the set of switches SW′₁-SW′_{Q}), and each switch circuit shown in FIG. 11 may be regarded as a decoder circuit having switch stages coupled in series. Hence, the row decoder circuit 1128 may further reduce the number of traces. For example, if the photosensor array 1130 has 240 row control lines (i.e. M equals 240), using the row decoder circuit 1128 may reduce the number of traces from 240 to 36, wherein 30 traces are signal traces connected to the control circuit 1122, and 6 traces are signal traces of the set of row selection signals S_{A1}-S_{A2}, S_{B1}-S_{B2} and S_{C1}-S_{C2}.

Please note that the number of column selection signals and/or the number of sets of switches shown in FIG. 11 is for illustrative purposes only, and is not meant to be a limitation of the present invention. In one implementation, the switch stage adjacent to the column data line may have only one set of switches, and one row selection signal of each set of row selection signals may be an inverting signal of another row selection signal thereof (e.g. row selection signal S_{A1} and the row selection signal S_{A2}).

Although only one of a column decoder circuit and a row decoder circuit is shown in each of the embodiments shown in FIG. 8-FIG. 11, it is feasible to dispose both of the column decoder circuit shown in FIG. 8/FIG. 9 and the row decoder circuit shown in FIG. 10/FIG. 11 (e.g. the architecture of the image sensing apparatus 700 shown in FIG. 7). Additionally, an image apparatus employing the decoder circuits shown in FIG. 8-FIG. 11 is not limited to any of the image sensing apparatus shown in FIG. 1-FIG. 5.

In view of above, when the proposed column decoder circuits and/or row decoder circuits are disposed on a substrate of an image sensing apparatus, the number of traces disposed on the substrate may be greatly decreased. For example, if a column decoder circuit (the column decoder circuit 826 shown in FIG. 8 or the column decoder circuit 926 shown in FIG. 9) and/or a row decoder circuit (the row decoder circuit 1028 shown in FIG. 10 or the row decoder circuit 1128 shown in FIG. 11) is disposed on the substrate 132 shown in FIG. 1, the number of traces between the substrate 132 and the signal processor 150 may be greatly decreased, thus lowering production cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image sensing apparatus, comprising:
a substrate, having a first side;
a light guide plate, having a light exit surface and a light entry surface, wherein the light exit surface faces the first side of the substrate;
a plurality of photosensors, disposed on the first side of the substrate; and
a light source, disposed near the light entry surface of the light guide plate, wherein light generated from the light source enters the light guide plate through the light entry surface.

2. The image sensing apparatus of claim 1, wherein one of the substrate and the light guide plate further has a contact surface; and when an object contacts the contact surface to generate reflected light, the reflected light passes through the contact surface and falls on the photosensors.

3. The image sensing apparatus of claim 2, wherein the contact surface is a second side opposite to the first side of the substrate.

4. The image sensing apparatus of claim 2, wherein the contact surface is a surface opposite to the light exit surface of the light guide plate.

5. The image sensing apparatus of claim 4, wherein a medium is located between the substrate and the light guide plate, and a refractive index of the medium is higher than a refractive index of the light guide plate.

6. The image sensing apparatus of claim 5, wherein the medium is air.

7. The image sensing apparatus of claim 5, wherein the light exit surface is a first surface of the light guide plate; the light entry surface is a lateral side of the light guide plate; the light guide plate further has a second surface opposite to the first surface; and when an object touches the second surface to generate reflected light, the reflected light passes through the second surface and travels toward the photosensors through the first surface.

8. The image sensing apparatus of claim 3, wherein the substrate has transparency, and the light generated from the light source falls on the substrate from the light exit surface after entering the light guide plate.

9. The image sensing apparatus of claim 1, wherein the substrate has transparency, and the light generated from the light source travels toward the substrate from the light exit surface after entering the light guide plate.

10. The image sensing apparatus of claim 9, wherein the light exit surface of the light guide plate abuts against the first side of the substrate.

11. The image sensing apparatus of claim 9, further comprising:
a plurality of light shielding devices, disposed respectively in correspondence with the photosensors, the light shielding devices arranged for preventing the light generated from the light source from falling on the photosensors directly, wherein each light shielding device is disposed at a side of a corresponding photosensor, and the side of the corresponding photosensor faces the light exit surface.

12. The image sensing apparatus of claim 9, wherein the light exit surface is a first surface of the light guide plate, and the light entry surface is a second surface opposite to the first surface of the light guide plate or a lateral side of the light guide plate.

13. The image sensing apparatus of claim 12, wherein the light entry surface is the lateral side of the light guide plate, and the light guide plate comprises:
a microstructure, disposed on the second surface and in the light guide plate, the microstructure arranged for changing a travel path of the light generated from the light source in the light guide plate in order to enable the light generated from the light source to fall on the substrate.

14. The image sensing apparatus of claim 1, wherein a medium is located between the substrate and the light guide plate, and a refractive index of the medium is higher than a refractive index of the light guide plate.

15. The image sensing apparatus of claim 14, wherein the medium is air.

16. The image sensing apparatus of claim 14, wherein the light exit surface is a first surface of the light guide plate; the light entry surface is a lateral side of the light guide plate; the light guide plate further has a second surface opposite to the first surface; and when an object touches the second surface to generate reflected light, the reflected light passes through the second surface and travels toward the photosensors through the first surface.

17. The image sensing apparatus of claim 1, being a fingerprint image sensing apparatus.

18. The image sensing apparatus of claim 1, wherein the substrate is a glass substrate.

19. The image sensing apparatus of claim 1, wherein each photosensor comprises:
a transistor, having a control terminal, a connection terminal and a data terminal; and
a photodiode, coupled to the connection terminal, the photodiode arranged for receiving reflected light generated in response to a touch of an object on the light guide plate or the substrate, and accordingly generating a sensing signal to the connection terminal;
and the image sensing apparatus further comprises:
a control circuit, coupled to a control terminal of each transistor, the control circuit arranged for controlling the transistor to output a corresponding sensing signal from a data terminal of the transistor.

20. The image sensing apparatus of claim 1, wherein the photosensors are arranged in a photosensor array; each photosensor receives reflected light generated in response to a touch of an object on the light guide plate or the substrate, and accordingly generates a sensing signal; the photosensor array has a plurality of rows, a plurality of row control lines, a plurality of columns and a plurality of column data lines; and the image sensing apparatus further comprises:
a control circuit, for controlling a plurality of photosensors of each row by a row control line of the row in order to transmitting a plurality of sensing signals of the row to a plurality of column data lines of the row, and generating at least one set of column selection signals, wherein each set of column selection signals comprises a plurality of column selection signals;
a processing circuit, having at least one input terminal, the processing circuit arranged for processing a plurality of sensing signals of the column data lines to obtain an image of the object; and
a column decoder circuit, coupled to the control circuit, the processing circuit and the photosensor array, wherein the column decoder circuit couples the column data lines to the at least one input terminal according to the at least one set of column selection signals, and comprises:
at least one switch stage, controlled by the at least one set of column selection signals respectively, wherein the at least one switch stage has a plurality of input nodes and at least one output node, and couples the input nodes to the at least one output node according to the at least one set of column selection signals.

21. The image sensing apparatus of claim 20, wherein each switch stage comprises at least one set of switches, and each set of switches has a plurality of input nodes and an output node, and couples one of the input nodes of the set of switches to the output node of the set of switches according to a set of column selection signals of the corresponding switch stage.

22. The image sensing apparatus of claim 20, wherein when the at least one switch stage is a specific switch stage adjacent to the photosensor array, the specific stage comprises a plurality of sets of switches, and input nodes of the sets of switches are coupled to the column data lines, respectively; and when the at least one switch stage is a specific switch stage adjacent to the processing circuit, the specific stage comprises at least one set of switches, and at least one output node of the at least one set of switches is coupled to the at least one input terminal, respectively.

23. The image sensing apparatus of claim 20, wherein the at least one set of column selection signals comprises a plurality of sets of column selection signals; the at least one switch stage comprises a plurality of switch stages coupled to each other; the switch stages are controlled by the sets of column selection signals, respectively; and the column decoder circuit couples the column data lines to the at least one input terminal through the switch stages according to the sets of column selection signals.

24. The image sensing apparatus of claim 1, wherein the photosensors are arranged in a photosensor array; the photosensor array has a plurality of rows, a plurality of row control lines, a plurality of columns and a plurality of column data lines; and the image sensing apparatus further comprises:
a control circuit, for generating a plurality of row control signals and at least one set of row selection signals, wherein the row control lines comprises a plurality of groups of row control lines; the row control signals are coupled to the groups of row control lines, respectively, and each set of row selection signals comprises a plurality of row selection signals; and
a row decoder circuit, coupled to the control circuit and the photosensor array, the row decoder circuit comprising:
a plurality of switch circuits, disposed respectively in correspondence with the columns, wherein each switch circuit couples a plurality of photosensors of a column corresponding to the switch circuit to a column data line corresponding to the column according to the at least one set of row selection signals, and comprises:
at least one switch stage, controlled by the at least one set of row selection signals respectively, wherein the at least one switch stage has a plurality of input nodes and at least one output node, and couples the input nodes to the at least one output node according to the at least one set of row selection signals.

25. The image sensing apparatus of claim 24, wherein each switch stage comprises a plurality of sets of switches, and each set of switches comprises a plurality of input nodes and an output node, and couples one of the input nodes of the set of switches to the output node of the set of switches according to a set of row selection signals of the corresponding switch stage.

26. The image sensing apparatus of claim 24, wherein when the at least one switch stage is a specific switch stage adjacent to the photosensors of the column, input nodes of the specific switch stage are coupled to the photosensors of the column, respectively; and when the at least one switch stage is a specific switch stage adjacent to the column data line of the column, the output node of the specific switch stage is coupled to the column data line of the column.

27. The image sensing apparatus of claim 24, wherein the at least one set of row selection signals comprises a plurality of sets of row selection signals; the at least one switch stage comprises a plurality of switch stages coupled to each other; the switch stages are controlled by the sets of row selection signals, respectively; and each switch circuit couples photosensors corresponding to the switch circuit to a column data line corresponding to the switch circuit through the switch stages according to the sets of row selection signals.

28. A decoder circuit of an image sensing apparatus, the image sensing apparatus comprising a photosensor array and a processing circuit; the photosensor array having a plurality of rows, a plurality of row control lines, a plurality of columns and a plurality of column data lines; the processing circuit having at least one input terminal and arranged for processing a plurality of sensing signals of the column data lines; the decoder circuit comprising:
a control circuit, for generating at least one set of column selection signals, wherein each set of column selection signals comprises a plurality of column selection signals; and
a column decoder circuit, coupled to the control circuit, the processing circuit and the photosensor array, wherein the column decoder circuit couples the column data lines to the at least one input terminal according to the at least one set of column selection signals, and comprises:
at least one switch stage, controlled by the at least one set of column selection signals respectively, wherein the at least one switch stage has a plurality of input nodes and at least one output node, and couples the input nodes to the at least one output node according to the at least one set of column selection signals.

29. The decoder circuit of claim 28, wherein each switch stage comprises at least one set of switches, and each set of switches has a plurality of input nodes and an output node, and couples one of the input nodes of the set of switches to the output node of the set of switches according to a set of column selection signals of the corresponding switch stage.

30. The decoder circuit of claim 28, wherein when the at least one switch stage is a specific switch stage adjacent to the photosensor array, the specific stage comprises a plurality of sets of switches, and input nodes of the sets of switches are coupled to the column data lines, respectively; and when the at least one switch stage is a specific switch stage adjacent to the processing circuit, the specific stage comprises at least one set of switches, and at least one output node of the at least one set of switches is coupled to the at least one input terminal, respectively.

31. The decoder circuit of claim 28, wherein the at least one set of column selection signals comprises a plurality of sets of column selection signals; the at least one switch stage comprises a plurality of switch stages coupled to each other; the switch stages are controlled by the sets of column selection signals, respectively; and the column decoder circuit couples the column data lines to the at least one input terminal through the switch stages according to the sets of column selection signals.

32. The decoder circuit of claim 31, wherein the switch stages comprises a first switch stage, a second switch stage and a third switch stage; the second switch stage is coupled in series between the first switch stage and the third switch stage; and input nodes of the second switch stage are coupled to output nodes of the first switch stage, respectively, and output nodes of the second switch stage are coupled to input nodes of the third switch stage, respectively.

33. A decoder circuit of an image sensing apparatus, the image sensing apparatus comprising a photosensor array; the photosensor array having a plurality of rows, a plurality of row control lines, a plurality of columns and a plurality of column data lines; and the decoder circuit comprising:
a control circuit, for generating a plurality of row control signals and at least one set of row selection signals, wherein the row control lines comprises a plurality of groups of row control lines; the row control signals are coupled to the groups of row control lines, respectively, and each set of row selection signals comprises a plurality of row selection signals; and
a row decoder circuit, coupled to the control circuit and the photosensor array, the row decoder circuit comprising:
a plurality of switch circuits, disposed respectively in correspondence with the columns, wherein each switch circuit couples a plurality of photosensors of a column corresponding to the switch circuit to a column data line corresponding to the column according to the at least one set of row selection signals, and comprises:
at least one switch stage, controlled by the at least one set of row selection signals respectively, wherein the at least one switch stage has a plurality of input nodes and at least one output node, and couples the input nodes to the at least one output node according to the at least one set of row selection signals.

34. The decoder circuit of claim 33, wherein each switch stage comprises a plurality of sets of switches, and each set of switches comprises a plurality of input nodes and an output node, and couples one of the input nodes of the set of switches to the output node of the set of switches according to a set of row selection signals of the corresponding switch stage.

35. The decoder circuit of claim 33, wherein when the at least one switch stage is a specific switch stage adjacent to the photosensors of the column, input nodes of the specific switch stage are coupled to the photosensors of the column, respectively; and when the at least one switch stage is a specific switch stage adjacent to the column data line of the column, the output node of the specific switch stage is coupled to the column data line of the column.

36. The decoder circuit of claim 33, wherein the at least one set of row selection signals comprises a plurality of sets of row selection signals; the at least one switch stage comprises a plurality of switch stages coupled to each other; the switch stages are controlled by the sets of row selection signals, respectively; and each switch circuit couples photosensors corresponding to the switch circuit to a column data line corresponding to the switch circuit through the switch stages according to the sets of row selection signals.

37. The decoder circuit of claim 36, wherein the switch stages comprises a first switch stage, a second switch stage and a third switch stage; the second switch stage is coupled in series between the first switch stage and the third switch stage; and input nodes of the second switch stage are coupled to output nodes of the first switch stage, respectively, and output nodes of the second switch stage are coupled to input nodes of the third switch stage, respectively.
